(19) United States
(12) Patent Application Publication
(10) Pub. No.: US 2010/0147396 A1
(43) Pub. Date: Jun. 17, 2010

(54) Multiple-Substrate Transfer Apparatus and Multiple-Substrate Processing Apparatus

(75) Inventors: Takayuki Yamagishi, Kashiwazaki-shi (JP); Tamihiro Kobayashi, Nagaoka-shi (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 12/335,371

(22) Filed: Dec. 15, 2008

(51) Int. Cl. B08B 9/00; C23C 16/54; H01L 21/306

(52) U.S. Cl. 137/15.01; 118/719; 156/345.32; 257/E21.215; 257/E21.17

(57) ABSTRACT

A multiple-substrate processing apparatus includes: a reaction chamber comprised of two discrete reaction stations aligned one behind the other for simultaneously processing two substrates; a transfer chamber disposed underneath the reaction chamber, for loading and unloading substrates to and from the reaction stations simultaneously; and a load lock chamber disposed next to the transfer chamber. The transfer arm includes one or more end-effectors for simultaneously supporting two substrates one behind the other as viewed in the substrate-loading/unloading direction.

### BACKGROUND

1. Field of the Invention

The present invention relates to a semiconductor manufacturing apparatus of vacuum load-lock type, or specifically to the structure and operating method of a compact sheet-feed semiconductor apparatus capable of processing wafers efficiently and continuously or simultaneously, as well as of the gas line system and reactor unit of such apparatus.

2. Description of the Related Art

In general, the chambers of a conventional semiconductor apparatus of vacuum load-lock type used in the manufacture of semiconductor integrated circuits comprise a load lock chamber, a transfer chamber, and multiple reaction chambers (processing chambers) connected to the transfer chamber. In each chamber a wafer transfer robot that automatically supplies wafers is used and operates as follows. First, an atmospheric robot transfers a wafer from a wafer cassette or FOUP (a box equipped with removable wafer cassettes and a front-opening interface) into the load lock chamber. Next, the load lock chamber is evacuated, after which the wafer is transferred to each reaction chamber via a vacuum robot inside the common transfer chamber of a polygonal shape. After being processed in the reaction chamber, the wafer is transferred to the load lock chamber via the vacuum robot. Finally, the load lock chamber is returned to atmospheric pressure, after which the processed wafer is transferred out to a cassette or FOUP via the atmospheric robot. Such apparatus is generally called a “cluster tool.”

On the other hand, some apparatuses have a transfer mechanism inside the load lock chamber, where each reaction chamber is disposed next to the load lock chamber and connects to it via a gate valve, in order to reduce the footprint. With these apparatuses, however, it is difficult to charge wafers in-process into the load lock chamber during continuous processing, such as during a continuous CVD deposition process or when an etching process or ashing process is performed. As a solution, the transfer arm inside the load lock chamber can be changed to double arms. However, use of double transfer arms increases the volume of the load lock chamber, which then increases the time needed to evacuate the load lock chamber/return it to atmospheric pressure, thereby consequently limiting the wafer transfer rate. Also, the structure itself is such that film deposits easily around the gate valve, just like in conventional cluster tools. In the case of a plasma CVD apparatus, etc., O-rings and other parts that are resistant to plasma and therefore expensive are also required.

To solve the aforementioned problems, the inventors of the invention proposed under the present application for patent devised an apparatus comprising a transfer chamber disposed below a reaction chamber, thereby isolating a gate valve from the reaction chamber (U.S. Pat. No. 6,899,507), and also devised an apparatus having a buffer mechanism for the purpose of improving the limitation on the wafer transfer rate (U.S. Patent Application Publication No. 2008/0056854 A1).

### SUMMARY

The present invention improves the apparatuses devised earlier by the inventors, where its object in an embodiment is to provide a semiconductor manufacturing apparatus that achieves a lower cost per throughput, smaller footprint, smaller faceprint and higher throughput.

Embodiments of the present invention include, but are not limited to, a multiple-substrate processing apparatus comprising: (a) a reaction chamber comprised of two discrete reaction stations for simultaneously processing two substrates, said reaction stations being aligned along a substrate-loading/unloading direction; (b) a transfer chamber disposed underneath the reaction chamber, for loading and unloading substrates to and from the reaction stations; (c) a load lock chamber disposed next to the transfer chamber, said load lock chamber being provided with a transfer arm for loading and unloading substrates to and from the transfer chamber, said transfer arm comprising one or more end-effectors for simultaneously supporting two substrates one behind the other as viewed in the substrate-loading/unloading direction; and (d) a transfer robot disposed in the vicinity of the load lock chamber, for loading and unloading substrates to and from the transfer arm.

In another aspect, embodiments of the present invention include, but are not limited to, a method for controlling exhaust flow in an embodiment of the multiple-substrate processing apparatus, comprising: (i) evacuating both the reaction chamber and the transfer chamber selectively through the exhaust port of the transfer chamber rather than through the exhaust port of the reaction chamber, when substrates are in the transfer chamber; (ii) evacuating the reaction chamber selectively through the exhaust port of the reaction chamber rather than through the exhaust port of the transfer chamber, while introducing a pure gas into the transfer chamber, when substrates are in the reaction chamber for processing; and (iii) evacuating the reaction chamber predominantly or wholly through the exhaust port of the reaction chamber rather than through the exhaust port of the transfer chamber, when the reaction chamber is subjected to cleaning. As used herein, the term ‘evacuate’ shall mean the removal of some or all of the contents of a chamber.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale. Further, the drawings omit some parts for explanatory purposes and an easy understanding of the structures.

FIG. 1 is a schematic plan view of a multiple-substrate processing apparatus according to an embodiment of the present invention.

FIG. 2 is a schematic cross-sectional side view of a reaction chamber according to an embodiment of the present invention.

FIGS. 3A to 3C are schematic perspective views showing movement of substrates wherein a first substrate is loaded in a load lock chamber (FIG. 3A), a second substrate is loaded in the load lock chamber (FIG. 3B), and the two substrates are moved to a reaction chamber (FIG. 3C) according to an embodiment of the present invention.

FIG. 4A is a schematic perspective view of a guiding mechanism for end-effectors according to an embodiment of the present invention.

FIG. 4B is a schematic perspective enlarged view of a guide block and related structures according to an embodiment of the present invention.

FIG. 5 is a broken up perspective view from a bottom end of a buffer mechanism according to an embodiment of the present invention.

FIG. 6 shows schematic diagrams of reactor operations in an embodiment of the present invention.

FIG. 7 is a schematic illustration of the gas and vacuum lines according to one embodiment of the present invention.

### DETAILED DESCRIPTION

As described above, embodiments of the present invention, which can resolve at least one of the problems in the conventional apparatuses, include a multiple-substrate processing apparatus comprising: (a) a reaction chamber comprised of two discrete reaction stations for simultaneously processing two substrates, said reaction stations being aligned one behind the other as viewed in a substrate-loading/unloading direction; (b) a transfer chamber disposed underneath the reaction chamber, for loading and unloading substrates to and from the reaction stations simultaneously; (c) a load lock chamber disposed next to the transfer chamber, said load lock chamber being provided with a transfer arm for loading and unloading substrates to and from the transfer chamber, said transfer arm comprising one or more end-effectors for simultaneously supporting two substrates one behind the other as viewed in the substrate-loading/unloading direction; and (d) a transfer robot disposed in the vicinity of the load lock chamber, for loading and unloading substrates to and from the transfer arm.

In an embodiment, the multiple-substrate processing apparatus may further comprise another reaction chamber, another transfer chamber, and another transfer arm, wherein the reaction chamber and the another reaction chamber, the transfer chamber and the another transfer chamber, and the transfer arm and the another transfer arm are disposed side by side, wherein the load lock chamber accommodates both the transfer arm and the another transfer arm, and the another transfer arm is accessible to the transfer robot. In an embodiment, the multiple-substrate processing apparatus may further comprise a common exhaust system connected to a dry pump which is shared by the reaction chamber, the another reaction chamber, the transfer chamber, and the another transfer chamber. In an embodiment, the multiple-substrate processing apparatus may further comprise four gas supply systems connected to the reaction stations of the reaction chamber and the reaction stations of the another reaction chamber, respectively.

In any of the foregoing embodiments, the reaction chamber, the transfer chamber, and the load lock chamber may be provided with different exhaust ports, wherein the exhaust port of the reaction chamber and the exhaust port of the transfer chamber are connected downstream of the reaction chamber and the transfer chamber and alternately selected by a valve or valves.

In any of the foregoing embodiments, the exhaust port of the transfer chamber may be disposed at a position below substrates placed on susceptors provided for the respective reaction stations.

In any of the foregoing embodiments, the reaction chamber and the transfer chamber may be separated by susceptors and insulative isolation plates when the susceptors are at a processing position for processing substrates placed on the susceptors, and the transfer chamber may be provided with a gas inlet port for introducing gas into the transfer chamber during processing and cleaning to inhibit reaction/cleaning gas in the reaction chamber from entering the transfer chamber.

In any of the foregoing embodiments, the reaction chamber may be provided with an exhaust port, each reaction station may be surrounded by an exhaust duct, the exhaust duct of one of the reaction stations and the exhaust duct of another of the reaction stations may be connected to each other, and one of the exhaust ducts may be connected to the exhaust port. In an embodiment, the exhaust ducts may be made of an insulative material.

In any of the foregoing embodiments, the transfer chamber may be provided with a buffer mechanism for temporarily accommodating two substrates one above the other in the transfer chamber.

In any of the foregoing embodiments, the one or more end-effectors of the transfer arm may be constituted by an upper end-effector and a lower end-effector.

In any of the foregoing embodiments, the reaction stations may be each provided with showerheads serving as electrodes for plasma treatment, such as in plasma enhanced chemical vapor deposition (PECVD).

In another aspect, embodiments of the present invention include a method for controlling exhaust flow in any of the foregoing embodiments of the multiple-substrate processing apparatuses, comprising: (i) evacuating both the reaction chamber and the transfer chamber selectively through the exhaust port of the transfer chamber rather than through the exhaust port of the reaction chamber, when substrates are in the transfer chamber; (ii) evacuating the reaction chamber selectively through the exhaust port of the reaction chamber rather than through the exhaust port of the transfer chamber, while introducing a purge gas into the transfer chamber, when substrates are in the reaction chamber for processing; and (iii) evacuating the reaction chamber predominantly or wholly through the exhaust port of the reaction chamber rather than through the exhaust port of the transfer chamber, when the reaction chamber is subjected to cleaning.

In an embodiment, the exhaust port of the reaction chamber and the exhaust port of the transfer chamber may be connected downstream of the reaction chamber and the transfer chamber, and the selection of the exhaust port of the reaction chamber or the exhaust port of the transfer chamber may be performed by controlling a valve provided in the vicinity of the connection point.

Embodiments will be explained below with reference to the drawings. However, the embodiments and drawings are not intended to limit the present invention.

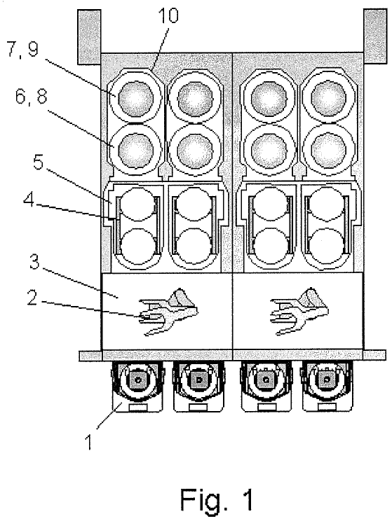

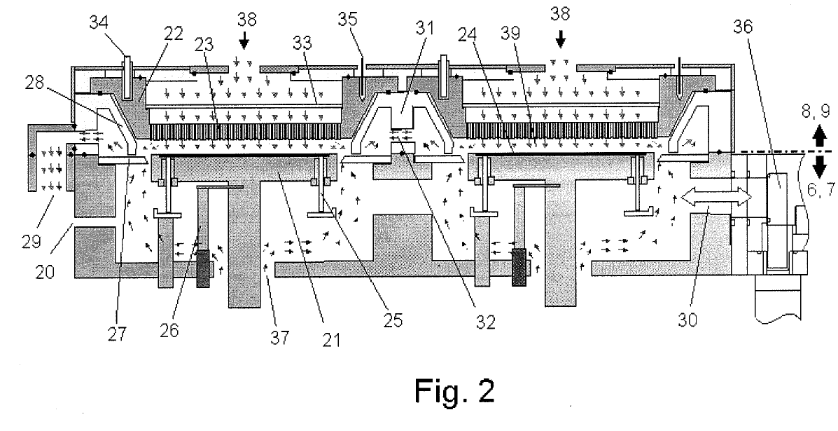

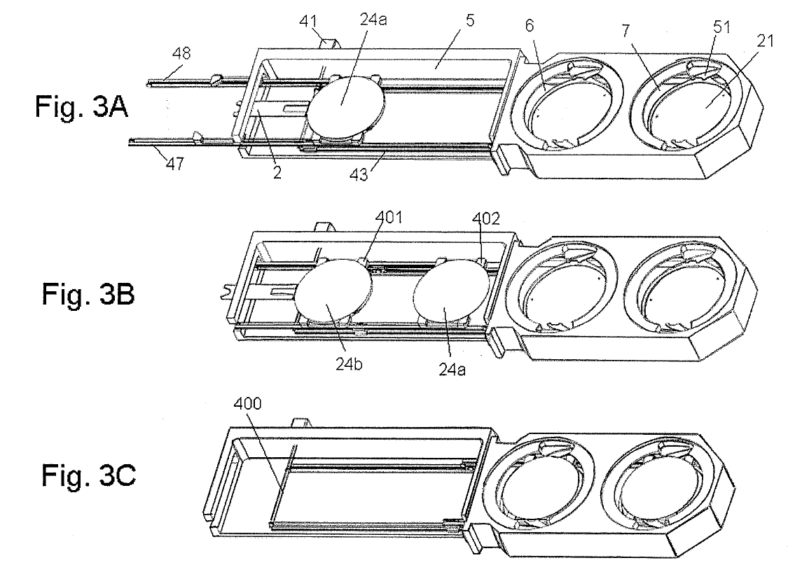

FIG. 1 is a schematic plan view of a multiple-substrate processing apparatus according to an embodiment of the present invention. This figure shows two apparatuses (modules or reaction units) disposed side by side. Each apparatus has a left side and a right side, and each side comprises a FOUP or cassette 1, a mini-environment 3 in which an atmospheric robot 2 is disposed, a load lock chamber 5, and a reactor 10 connected to the load lock chamber 5. The reactor 10 comprises a reaction chamber comprised of two discrete reaction stations 8, 9 and a transfer chamber comprised of two discrete transfer stations 6, 7 disposed underneath the reaction stations 8, 9, respectively, as shown in FIG. 2. FIG. 2 is a schematic cross-sectional side view of a reaction chamber according to an embodiment of the present invention. The reaction stations 8, 9 are aligned one behind the other as viewed in a substrate-loading/unloading direction. In FIG. 1, the substrate-loading/unloading direction is oriented within or parallel to the plane of the figure and through the transfer stations 6, 7 and load lock chamber 5, and in FIG. 2 it is oriented horizontally within or parallel to the plane of the figure. The transfer chamber is disposed underneath the reaction chamber, for loading and unloading substrates to and from the reaction stations simultaneously. The load lock chamber 5 is disposed next to the transfer station 6 of the transfer chamber. The load lock chamber is provided with a transfer arm 4 for loading and unloading substrates to and from the transfer stations 6, 7. The transfer arm 4 comprises end-effectors 401, 402 for simultaneously supporting two substrates one behind another as viewed in the substrate-loading/unloading direction as shown in FIGS. 3A to 3C (which are explained below). In alternative embodiments, the transfer arm 4 can have a single end-effector for simultaneously supporting the two substrates, rather than a pair of end-effectors 401, 402. The atmospheric robot 2 is disposed in the vicinity of the load lock chamber 5, for loading and unloading substrates to and from the transfer arm 4.

The transfer station 6 is disposed underneath the reaction station 8 and is connected to the load lock chamber 5 via a gate valve 36. Thus, the gate valve 36 does not face the interior of the reaction station and is not exposed to plasma discharge, thereby suppressing formation of film around the gate valve and suppressing generation of contaminants.

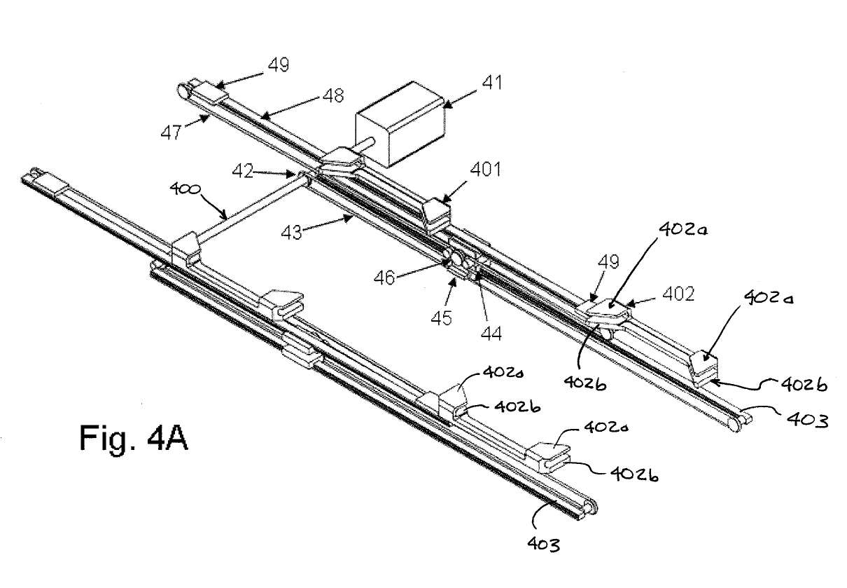

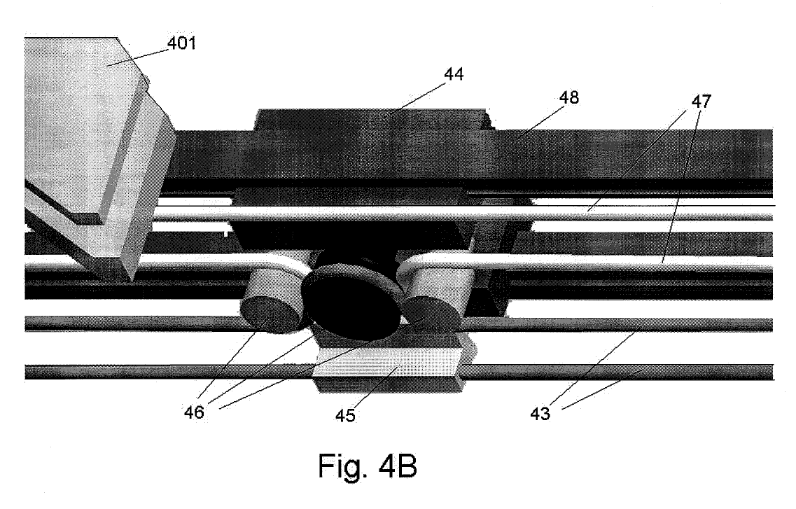

Each of the end-effectors 401, 402 of the transfer arm 4 comprises an upper end-effector 401a, 402a and a lower end-effector 401b, 402b as shown in FIG. 4A (which are explained below).

The atmospheric robot 2 can move laterally side to side and back and forth to transfer substrates between the FOUP 1 and the load lock chamber 5. Further, the atmospheric robot 2 can move vertically so that it can be positioned at the upper end-effector 401a, 402a and at the lower end-effector 401b, 402b. That is, the atmospheric robot 2 unloads a substrate (e.g., a processed substrate) from the lower end-effector 401b, 402b in the load lock chamber 5 and carries it to the FOUP 1, and also the atmospheric robot 2 carries a substrate (e.g., an unprocessed substrate) from the FOUP 1 and loads it to the upper end-effector 401a, 402a. In one embodiment, the atmospheric robot 2 comprises structures and mechanisms disclosed in U.S. Patent Application Publication No. 2008/0056854 A1, the entire disclosure of which is herein incorporated by reference, especially with regard to the structures and mechanisms of the atmospheric robot shown in FIGS. 1, 3(a), and 3(b), and the related text.

As shown in FIG. 2, the reaction chamber 8, 9 and the transfer chamber 6, 7 are separated by susceptors 21 and insulative isolation plates 27 when the susceptors are at a processing position for processing substrates placed on the susceptors, and the transfer chamber 6, 7 is provided with a gas inlet port 37 for introducing gas into the transfer chamber 6, 7 during processing and cleaning to inhibit reaction/cleaning gas in the reaction chamber from entering the transfer chamber 6, 7. The reaction stations 8, 9 include inlets 38 for receiving reactants for substrate processing, and also cleaning gas during cleaning operations. A showerhead 22 comprises a shower plate 23 and a diffusion plate 33, and gas is supplied to a reaction space 39 through many holes provided in the shower plate 23. The showerhead is provided with a heater 34 and a thermo coupling 35. The reaction chamber is provided with an exhaust port 29. Each reaction station 8, 9 is surrounded by an exhaust duct 28. The exhaust duct 28 of the reaction station 8 and the exhaust duct 28 of the reaction station 9 are connected to each other at a connection point 31 via a connection channel 32, and the exhaust duct 28 of the reaction station 9 is connected to the exhaust port 29. The exhaust duct 28 may be made of an insulative material such as ceramics.

The reaction chamber 8, 9, the transfer chamber 6, 7, and the load lock chamber 5 are provided with different exhaust ports, wherein the exhaust port 29 of the reaction chamber and the exhaust port 20 of the transfer chamber are connected downstream of the reaction chamber 8, 9 and the transfer chamber 6, 7 and alternately selected by a valve. The exhaust port 20 of the transfer chamber 6, 7 is disposed at a position below a substrate 24 placed on a susceptor 21. The susceptor 21 is provided with lift pins 25. While the substrate 24 is being transferred or at a stand-by position within the transfer chamber, the transfer chamber 6, 7 and the reaction chamber 8, 9 can be selectively evacuated through the exhaust port 20 rather than through the exhaust port 29 of the reaction chamber, thereby inhibiting generation of particles during the process of transferring the substrate, inhibiting adhesion of particles which have been generated during film formation onto the substrate. During film formation on the substrates in the reaction stations, the exhaust port 20 can be closed, and the exhaust port 29 can be opened, thereby inhibiting expansion of the reaction space (i.e., inhibiting the reaction gas from entering the transfer chamber). Further, purge gas can be introduced into the transfer chamber 6, 7 through the port 37 when the substrates are in the reaction chamber for processing, thereby inhibiting reaction gas from entering the transfer chamber 6, 7. During cleaning, the gas flows can be basically the same as those used during film formation on the substrates, except that the exhaust port 20 can be opened as necessary so that cleaning gas delivered to the reaction chamber 8, 9 enters into and flows through the transfer chamber 6, 7, cleaning the interior walls of the transfer chamber 6, 7.

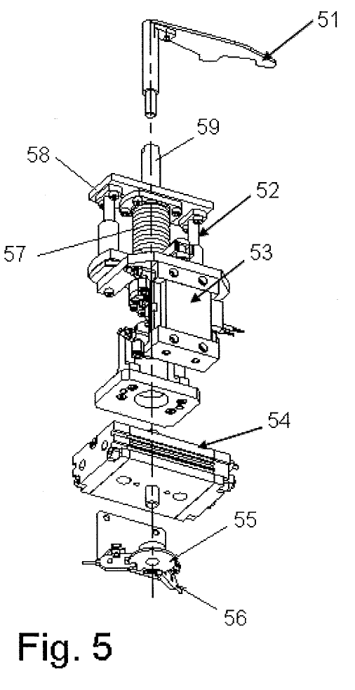

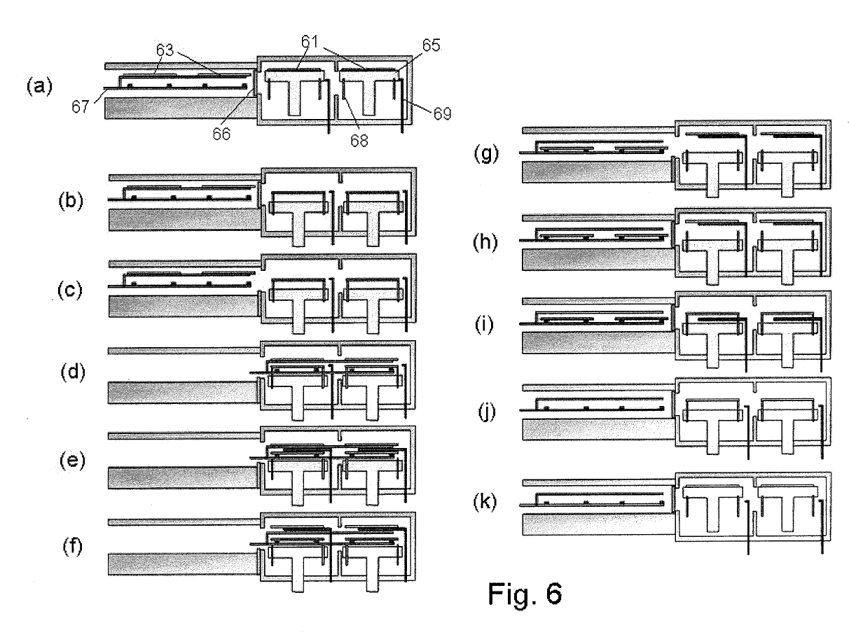

Due to the structure where the transfer chamber stations 6, 7 are disposed underneath the reaction chamber stations 8, 9, a buffer mechanism 26 can be employed, thereby improving productivity. FIG. 5 is a broken up perspective view from a bottom end of a buffer mechanism according to an embodiment of the present invention. The supporting apparatus for supporting a substrate is preferably a buffer fin 51. A portion 58 is fixed to a bottom of the reaction chamber. The buffer fin 51 is attached to a main shaft 59 which moves up and down using the up and down actuator 53 with slide shafts 52 which are disposed on both sides of the main shaft. The main shaft 59 is enclosed in the bellows 57 and sealed with an O-ring (not shown), so that even though the main shaft 59 rotates and ascends/descends inside the reactor, the interior of the reactor is sealed from the outside. The main shaft 59 rotates using the rotary actuator 54. The height of the buffer fin 51 is controlled using a sensor dog 55 and a photo electric sensor 56. In an embodiment, the buffer fin 51 can have three heights: high (buffer position), intermediate (unloading/loading position), and low (bottom position). In one embodiment, the buffer mechanism 26 comprises structures and mechanisms disclosed in U.S. Patent Application Publication No. 2008/0056854 A1, particularly at FIGS. 6(a) and 6(b) and the related text.

As described above, the transfer chamber has two transfer stations 6, 7 whose interiors are connected so that the transfer arm 4 can enter the transfer station 6 and then the transfer station 7 via the gate valve 36 through the opening 30, while the susceptors 21 are at a lower position (a transfer position). FIGS. 3A to 3C are schematic perspective views showing movement of substrates wherein a first substrate is loaded in a load lock chamber (FIG. 3A), a second substrate is loaded in the load lock chamber (FIG. 3B), and the two substrates are moved to a reaction chamber (FIG. 3C) according to an embodiment of the present invention. FIG. 4A is a schematic perspective view of a guiding mechanism for end-effectors according to an embodiment of the present invention. FIG. 4B is a schematic perspective enlarged view of a guide block and related structures according to an embodiment of the present invention. As shown in FIGS. 4A and 4B, the end-effectors 401, 402 are mounted on a linear guide rail 48 and move together with the linear guide rail 48 in a substrate-loading/unloading direction. A motor 41 is connected to a shaft 400 having a drive pulley 42. Operation of the motor 41 rotates the shaft 400 to rotationally drive the drive pulley 42, thereby moving a lower belt 43. A linear guide block 44 and the lower belt 43 are connected by a connecting member 45 and move together. When the lower belt 43 and the linear guide block 44 are moved, a linear guide block pulley 46 rotates, thereby moving an upper belt 47. Because the linear guide rail 48 is connected to the upper belt 47 by a connecting member 49, when the linear guide block pulley 46 rotates, the liner guide rail 48 and the end-effectors 401, 402 move in the substrate-loading/unloading direction, relative to the stationary track 403.

In FIG. 3A, the linear guide rail 48 is at a proximal position where its proximal end is located in the mini-environment 3. A first substrate 24a is loaded on the end-effector 402 (the upper end-effector 402a) in the load lock chamber 5 using the atmospheric robot 2. In FIG. 3B, the linear guide rail 48 is at an intermediate position where the linear guide rail 48 is located substantially inside the load lock chamber 5. A second substrate 24b is loaded on in the end-effector 401 (the upper end-effector 401a) in the load lock chamber 5 using the atmospheric robot 2. In FIG. 3C, the linear guide rail 48 is at a distal position where the linear guide rail 48 is located inside the transfer chamber 6, 7, where the first substrate 24a is in the transfer station 7, and the second substrate 24b is in the transfer station 6. When returning the processed substrates, the same operation with the reversed direction or sequence can be used using the lower end-effectors 401b, 402b.

In another embodiment, the atmospheric robot has a two-substrate length and can carry at once two substrates aligned one behind the other. In the embodiment, a transfer arm without the linear guide mechanism shown in FIGS. 3A to 3C can be used.

Suitable configurations and operation of the upper and lower end-effectors are disclosed in U.S. Patent Application Publication No. 2008/0056854 A1, particularly at FIGS. 4 and 5 and the related text.

An operation sequence utilizing the buffer mechanism according to an embodiment of the present invention is described below. FIG. 6 shows schematic diagrams of reactor operations in an embodiment. First, unprocessed substrates 63 are loaded on upper end-effectors of a transfer arm 67 in the load lock chamber (Process (a)). Susceptors 65 on which processed substrates 61 are placed in the reaction chamber are lowered, thereby supporting the processed substrates on lift pins 68 extending upward from the susceptors (for the first time, no processed substrates are in the reaction chamber) (Process (b)). A gate valve 66 is opened (Process (c)). Upon opening the gate valve 66, the transfer arm 67 is laterally extended from the load lock chamber to the reaction chamber, whereby the processed substrates 61 supported on the lift pins are located between the upper end-effectors and lower end-effectors of the transfer arm 67, and the unprocessed substrates are on the upper end-effectors (Process (d)). Buffer arms 69 (an example of which is shown in FIG. 5, described above) at an unloading/loading position rotate in a lateral direction/plane (about a vertical axis) toward the unprocessed substrates, and the unprocessed substrates are supported using the buffer arms 69 provided in the reaction chamber, thereby loading the unprocessed substrates on the buffer arms (Process (e)). The buffer arms 69 are raised to a buffer position with the unprocessed substrates while lowering the lift pins 68, thereby placing the processed substrates on the lower end-effectors (Process (f)). The transfer arm 67 is retracted from the reaction chamber to the load lock chamber (Process (g)). The gate valve 66 is then closed (Process (h)). The buffer arms 69 are lowered to a bottom position with the unprocessed substrates, thereby supporting the unprocessed substrates on the lift pins extending upward from the susceptors (Process (i)). The buffer arms 69 rotate in the lateral direction away from the unprocessed substrates to its home position (Process (j)). The susceptors are then raised and the lift pins 68 are retracted, thereby loading the unprocessed substrates on the susceptors (Process (k)). After Process (k), a processing recipe such as a deposition recipe can begin. The processed substrates in the load lock chamber are unloaded from the lower end-effectors and Process (a) is performed in the load lock chamber while processing the unprocessed substrates in the reaction chamber, followed by Processes (b) to (k).

The reaction chamber or reactor need not be a PECVD chamber. Rather, it can be any suitable chamber for any type of reaction including CVD (chemical vapor deposition), PVD (physical vapor deposition), and ALD (atomic layer deposition). Further, more than two reaction chambers can be disposed side by side, or a single reaction chamber can also be used, wherein each reaction chamber includes two reaction stations aligned one behind the other as viewed in the substrate-loading/unloading direction.

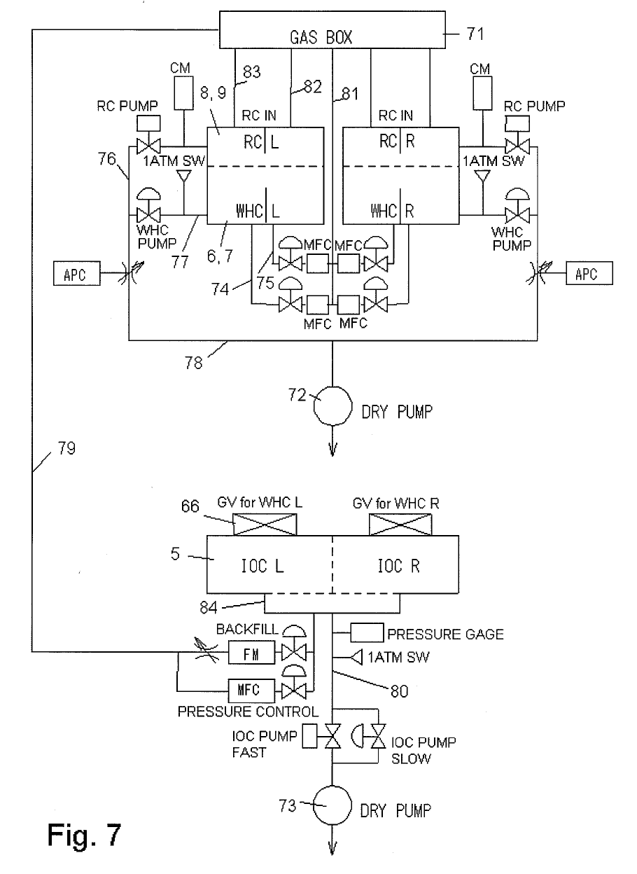

FIG. 7 is a schematic illustration of the gas and vacuum lines according to one embodiment of the present invention. The multiple-substrate processing apparatus is provided with two reaction chambers (RC/L, RC/R) each having two reaction stations, two transfer chambers (WHC/L, WHC/R) each having two transfer stations, two load lock chambers, and two transfer robots, wherein the two reaction chambers, the two transfer chambers, the two load lock chambers, and the two transfer robots are disposed side by side. The multiple-substrate processing apparatus comprises a common exhaust line 78 connected to a dry pump 72 which is shared by the reaction chambers and the transfer chambers. The multiple-substrate processing apparatus comprises two gas supply lines 82, 83 connected to the reaction stations of one of the reaction chambers and another two gas supply lines (unlabeled) connected to the reaction stations of the other reaction chamber, respectively. Gas is introduced into each transfer station through gas supply lines 74, 75 provided with mass flow controllers. The exhaust line 76 for the reaction chamber and the exhaust line 77 for the transfer chamber are connected downstream, leading to the dry pump 72 via a line 78 provided with an automatic pressure controller. Each of the exhaust lines 76, 77 is provided with a valve. All gas flows are controlled by a gas box 71. The load lock chamber is connected to a dry pump 73 through a line 80, and gas is introduced into the load lock chamber through a line 79. Line 80 is an exhaust line for the load lock chamber 5. Both lines 79 and 80 are connected to the load lock chamber via a common line 84. In an embodiment, the reactor employs gas and vacuum lines as disclosed in U.S. Pat. No. 6,899,507, the entire disclosure of which is herein incorporated by reference.

In the present disclosure where conditions and/or structures are not specified, the skilled artisan in the art can readily provide such conditions and/or structures, in view of the present disclosure, as a matter of routine experimentation.

The present invention includes the above mentioned embodiments and other various embodiments including the following:

1) A semiconductor manufacturing apparatus of vacuum load-lock type, comprising: a load lock chamber; a transfer chamber disposed next to the load lock chamber; a reaction chamber positioned above the transfer chamber; and a transfer robot provided outside the load lock chamber; such semiconductor manufacturing apparatus characterized in that the load lock chamber houses a wafer transfer arm that is constituted by a thin, link-type arm operable in vacuum to exchange wafers between the transfer robot and each chamber and one wafer transfer arm can have two wafers placed on it in the depth direction of the arm; one transfer chamber has two sets of wafer lift pins and susceptor heaters (lower electrodes); and one reaction chamber has two sets of shower plates (upper electrodes).

2) A semiconductor manufacturing apparatus of vacuum load-lock type according to 1) above, characterized in that the load lock chamber, transfer chamber and reaction chamber each have an exhaust port and when evacuation is performed, the exhaust port of the applicable transfer chamber is switched with the exhaust port of the applicable reaction chamber.

3) A semiconductor manufacturing apparatus of vacuum load-lock type according to 2) above, characterized in that the transfer chamber is evacuated at a position below the semiconductor wafers.

4) A semiconductor manufacturing apparatus of vacuum load-lock type according to any one of 1) to 3) above, characterized in that, during deposition and cleaning, the transfer chamber is virtually separated from the ambience of the reaction chamber by means of an insulating separation plate, and a mechanism is provided that introduces inert gas into the transfer chamber in order to prevent a reactant gas in the reaction chamber from flowing into the transfer chamber.

5) A semiconductor manufacturing apparatus of vacuum load-lock type according to any one of 1) to 4) above, characterized by the reaction chamber wherein an exhaust duct that also serves as a side wall of the reaction chamber is made of an insulative material in order to eliminate any negative impact on plasma deposition that uses high-frequency electric power or on cleaning reaction.

6) A semiconductor manufacturing apparatus of vacuum load-lock type according to any one of 1) to 5) above, characterized in that the layout where the transfer chamber is disposed below the reaction chamber prevents deposition of film around the gate valve which is provided to cut off the transfer chamber and reaction chamber from the load lock chamber, thereby eliminating the generation of foreign matters and enabling multiple deposition steps.

7) A semiconductor manufacturing apparatus of vacuum load-lock type according to any one of 1) to 6) above, characterized in that the layout where the transfer chamber is disposed below the reaction chamber allows for installation inside the transfer chamber of a mechanism (buffer mechanism) for temporarily storing wafers when the buffer transfer of wafers is conducted with the load lock chamber, which makes it possible to exchange wafers using only one expensive wafer transfer arm in the load lock chamber capable of operating in vacuum, and thereby permitting multiple deposition steps at low cost and consequently improving the productivity.

8) A semiconductor manufacturing apparatus of vacuum load-lock type, characterized in that the transfer arm according to any one of 1) to 7) above has end-effectors that hold wafers in two levels, and two loaded wafers and two unloaded wafers can be placed on them at the same time.

9) A semiconductor manufacturing apparatus of vacuum load-lock type, characterized in that the buffer mechanism according to 7) above is installed in a plurality of places at the outer periphery of the susceptor and the two-level end-effectors installed on the transfer arm inside the load lock chamber are used to buffer unprocessed wafers, while simultaneously collecting processed wafers, in a single extension/contraction movement.

10) A semiconductor manufacturing apparatus of vacuum load-lock type, characterized in that the buffer mechanism according to 7) or 9) above involves moving up and down a mechanism part retrieved via bellows, using an electrical or pneumatic cylinder mechanism, as well as rotation of a shaft retrieved to the outside in a manner sealed by an O-ring, etc., using an electrical or pneumatic rotary actuator.

11) A semiconductor manufacturing apparatus of vacuum load-lock type according to any one of 1) to 10) above, characterized in that processed wafers and unprocessed wafers in the load lock chamber can be swapped during processing inside the reaction chamber, and even when the wafer transfer mechanism in the load lock chamber has one transfer arm for each reactor, a capability equivalent to or greater than the level when double arms are used is ensured and thereby the volume of the load lock chamber can be reduced.

12) A semiconductor manufacturing method that uses a semiconductor manufacturing apparatus according to any one of 1) to 11) above.

13) A method characterized in that, during wafer transfer or standby, evacuation is performed at a position lower than the wafer transfer surface in order to prevent attachment to wafers of particles that generate during wafer transfer or particles that generate during deposition; during deposition, the exhaust port is switched from the one on the transfer chamber side to the other on the reaction chamber side in order to reduce the reaction chamber size, and at the same time purge gas is introduced from the transfer chamber side to prevent reactant gas from flowing toward the transfer chamber; and during cleaning, basically the same exhaust method used during deposition is applied, but if necessary the exhaust port of the transfer chamber can be used for cleaning so as to enable cleaning inside the transfer chamber.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A multiple-substrate processing apparatus comprising:
a reaction chamber comprised of two discrete reaction stations for simultaneously processing two substrates, said reaction stations being aligned along a substrate-loading/unloading direction;
a transfer chamber disposed underneath the reaction chamber, for loading and unloading substrates to and from the reaction stations;
a load lock chamber disposed next to the transfer chamber, said load lock chamber being provided with a transfer arm for loading and unloading substrates to and from the transfer chamber, said transfer arm comprising one or more end-effectors for simultaneously supporting two substrates one behind the other as viewed in the substrate-loading/unloading direction; and
a transfer robot disposed in the vicinity of the load lock chamber, for loading and unloading substrates to and from the transfer arm.

2. The multiple-substrate processing apparatus according to claim 1, further comprising another reaction chamber, another transfer chamber, and another transfer arm, wherein the reaction chamber and the another reaction chamber, the transfer chamber and the another transfer chamber, and the transfer arm and the another transfer arm are disposed side by side, wherein the load lock chamber accommodates both the transfer arm and the another transfer arm, and the another transfer arm is accessible to the transfer robot.

3. The multiple-substrate processing apparatus according to claim 2, further comprising a common exhaust system connected to a dry pump which is shared by the reaction chamber, the another reaction chamber, the transfer chamber, and the another transfer chamber.

4. The multiple-substrate processing apparatus according to claim 3, wherein the another reaction chamber comprises two discrete reaction stations for simultaneously processing two substrates, said reaction stations of the another reaction chamber being aligned along the substrate-loading/unloading direction, the multiple-substrate processing apparatus further comprising four gas supply systems each connected to a different one of the two reaction stations of the reaction chamber and the two reaction stations of the another reaction chamber.

5. The multiple-substrate processing apparatus according to claim 1, wherein the reaction chamber, the transfer chamber, and the load lock chamber are provided with different exhaust ports, wherein the exhaust port of the reaction chamber and the exhaust port of the transfer chamber are connected downstream of the reaction chamber and the transfer chamber and alternately selected by a valve or valves.

6. The multiple-substrate processing apparatus according to claim 5, wherein the exhaust port of the transfer chamber is disposed at a position below substrates placed on susceptors provided for the respective reaction stations.

7. The multiple-substrate processing apparatus according to claim 1, wherein each reaction station has an associated susceptor having a lowered position and a raised processing position, and wherein the reaction chamber and the transfer chamber are separated by the susceptors and insulative isolation plates when the susceptors are at the processing position for processing substrates placed on the susceptors, and the transfer chamber is provided with a gas inlet port for introducing gas into the transfer chamber during processing and cleaning to inhibit reaction/cleaning gas in the reaction chamber from entering the transfer chamber.

8. The multiple-substrate processing apparatus according to claim 1, wherein the reaction chamber is provided with an exhaust port, each reaction station is surrounded by an exhaust duct, the exhaust duct of one of the reaction station and the exhaust duct of another of the reaction station are connected each other, and one of the exhaust ducts is connected to the exhaust port.

9. The multiple-substrate processing apparatus according to claim 8, wherein the exhaust ducts are made of an insulative material.

10. The multiple-substrate processing apparatus according to claim 1, wherein the transfer chamber is provided with a buffer mechanism for temporarily accommodating two substrates one above the other in the transfer chamber.

11. The multiple-substrate processing apparatus according to claim 10, wherein the one or more end-effectors of the transfer arm comprise an upper end-effector and a lower end-effector.

12. The multiple-substrate processing apparatus according to claim 1, wherein the reaction stations are each provided with showerheads serving as electrodes for plasma treatment.

13. A method for controlling exhaust flow in a multiple-substrate processing apparatus comprising: (i) a reaction chamber comprised of two discrete reaction stations for simultaneously processing two substrates, said reaction stations being aligned one behind the other as viewed in a substrate-loading/unloading direction; (ii) a transfer chamber disposed underneath the reaction chamber, for loading and unloading substrates to and from the reaction stations; (iii) a load lock chamber disposed next to the transfer chamber, said load lock chamber being provided with a transfer arm for loading and unloading substrates to and from the transfer chamber, said transfer arm comprising one or more end-effectors for simultaneously supporting two substrates one behind the other as viewed in the substrate-loading/unloading direction; and (iv) a transfer robot disposed in the vicinity of the load lock chamber, for loading and unloading substrates to and from the transfer arm, wherein an exhaust port is provided in the reaction chamber above a substrate processing level at which substrates are placed for treatment, and an exhaust port is provided in the transfer chamber below the substrate processing level, said method comprising:
evacuating both the reaction chamber and the transfer chamber selectively through the exhaust port of the transfer chamber rather than through the exhaust port of the reaction chamber, when substrates are in the transfer chamber;
evacuating the reaction chamber selectively through the exhaust port of the reaction chamber rather than through the exhaust port of the transfer chamber, while introducing a purge gas into the transfer chamber, when substrates are in the reaction chamber for processing; and
evacuating the reaction chamber predominantly or wholly through the exhaust port of the reaction chamber rather than through the exhaust port of the transfer chamber, when the reaction chamber is subjected to cleaning.

14. The method according to claim 13, wherein the exhaust port of the reaction chamber and the exhaust port of the transfer chamber are connected downstream of the reaction chamber and the transfer chamber, and the selection of the exhaust port of the reaction chamber or the exhaust port of the transfer chamber is performed by controlling a valve or valves provided in the vicinity of the connection point.
